(19) United States
(12) Patent Application Publication
(10) Pub. No.: US 2026/0093000 A1
(43) Pub. Date: Apr. 2, 2026

(54) Acquisition of Diffusion-Weighted Measurement Data with Non-Trapezoidal Gradient Pulse Forms for Diffusion Encoding

(71) Applicant: Siemens Healthineers AG, Forchheim (DE)

(72) Inventor: Thorsten Feiweier, Poxdorf (DE)

(73) Assignee: Siemens Healthineers AG, Forchheim (DE)

(21) Appl. No.: 19/342,777

(22) Filed: Sep. 29, 2025

(30) Foreign Application Priority Data
Sep. 30, 2024 (DE) 10 2024 209 541.9

(51) Int. Cl. G01R 33/563; G01R 33/56

(52) U.S. Cl. CPC G01R 33/56341; G01R 33/5602; G01R 33/5608

(57) ABSTRACT

Techniques are provided to check that an acquisition of diffusion-weighted measurement data is able to be carried out with a magnetic resonance system when using a measurement protocol with non-trapezoidal gradient pulse waveforms for diffusion encoding. The techniques include loading of a non-trapezoidal gradient pulse waveform, loading of prepared characteristics for the non-trapezoidal gradient pulse waveform loaded, receiving of a condition that is to be fulfilled when the acquisition of the diffusion-weighted measurement data is carried out, determining at least one relevant gradient amplitude for the gradient pulse waveform on the basis of the loaded characteristics and of the condition, and checking that an acquisition of diffusion-weighted measurement data of the examination object with the magnetic resonance system is able to be carried out when using a measurement protocol with the non-trapezoidal gradient pulse waveform on the basis of the at least one relevant gradient amplitude determined.

### CROSS-REFERENCE TO RELATED APPLICATIONS

The present application claims priority to and the benefit of Germany patent application no. DE 10 2024 209 541.9, filed on Sep. 30, 2024, the contents of which are incorporated herein by reference in their entirety.

### TECHNICAL FIELD

The disclosure relates to improved planning of diffusion-weighted measurement data with non-trapezoidal gradient pulse forms for diffusion encoding.

### BACKGROUND

Magnetic resonance (MR) technology is a known technique with which images from the inside of an examination object can be created. Expressed in simple terms, to do this, the examination object is positioned in a magnetic resonance device in a comparatively strong static, homogeneous basic magnetic field, also called a B0 field, with field strengths of 0.2 tesla to 7 tesla and more, so that its nuclear spins are oriented along the basic magnetic field. To trigger nuclear spin resonances able to be measured as signals, radio-frequency excitation pulses (RF pulses) are radiated into the examination object, the triggered nuclear spin resonances are measured as so-called k-space data by means of coils designed to receive them and, on the basis of them, MR images are reconstructed or spectroscopy data is established. The magnetic alternating field created by the at least one excitation pulse irradiated in is also referred to as the B1 field. For location encoding of the measurement data, rapidly switched magnetic gradient fields, known as gradients for short, are overlaid on the basic magnetic field. A temporal course of such a gradient field, in the direction of a gradient axis for example, can also be referred as a gradient pulse form. A scheme used, which describes a temporal sequence of RF pulses to be irradiated in and gradients to be switched, is referred to a pulse sequence (scheme), or also as a sequence for short. The recorded measurement data is digitized and held as complex numerical values in a k-space matrix. An associated MR image is able to be reconstructed from the k-space matrix populated by values, by means of a multi-dimensional Fourier transformation for example.

Usually a magnetic resonance recording is composed of a plurality of individual part measurements, in which raw data is recorded from various slices of the examination object, from which volume image data can subsequently be reconstructed.

What is more, it is however also necessary with many applications to carry out a number, i.e. a whole series of, magnetic resonance recordings of the examination object, wherein a specific measurement parameter will be varied. With the aid of the measurements the effect of this measurement parameter on the examination object is observed, in order to then draw diagnostic conclusions from this later. A series in this case is understood as at least two, but as a rule more than two, magnetic resonance recordings. Sensibly, in such cases a measurement parameter is varied so that the contrast of a specific material type excited during the measurements, for example a tissue type of the examination object or of a chemical substance, which is significant for most of or for specific material types, such as for example water, is influenced as greatly as possible by the variation of the measurement parameter. This ensures that the effect of the measurement parameter on the examination object is visible especially well.

A typical example for series of magnetic resonance recordings while varying a measurement parameter greatly influencing the contrast are so-called diffusion weighted imaging (DWI)) methods, also called diffusion weighted imaging. Diffusion is understood as the Brownian motion of molecules in a medium. In diffusion imaging, as a rule a number of images with different diffusion directions and weightings are recorded and combined with one another. The strength of the diffusion weighting is mostly defined by what is known as the b value. The diffusion images with different diffusion directions and weightings, or the images combined from them, can then be used for diagnostic purposes. In this way, parameter maps with particular diagnostic expressive power are created from suitable combinations of the recorded diffusion-weighted images, such as for example maps that reflect the Apparent Diffusion Coefficient (ADC) or the Fractional Anisotropy (FA).

Frequently, the diffusion imaging is based on Echoplanar imaging (EPI) on account of the short acquisition time of EPI-sequences for each image and on their robustness in relation to movement.

In diffusion-weighted imaging, additional gradients are inserted into a pulse sequence to make the diffusion properties of the tissue visible or to measure them. These gradients lead to tissue with rapid diffusion (for example cerebro-spinal fluid (CSF) being subject to a greater signal loss than tissue with slow diffusion (for example the gray substance in the brain, (gray matter)). The resulting diffusion contrast is becoming clinically ever more important, and applications in the meantime are going far beyond the classic early detection of ischemic strokes.

### SUMMARY

For many years now, measurements of the diffusion characteristics in different types of tissue by means of magnetic resonance imaging have represented an indispensable tool for clinical diagnostics. Usually, in such cases diffusion encodings with two or more diffusion gradients with trapezoidal gradient pulse forms, as have already been described by Stejskal und Tanner in “Spin Diffusion Measurements: Spin Echoes in the Presence of a Time-Dependent Field Gradient”, J. Chem. Phys. 42: pp. 288-292 (1965), have been used, since these a) are efficient in respect of the utilization of the performance limits of a gradient system used and b) these are able to be easily described, both within the framework of diffusion models and also for technical calculations (for example regarding stimulations or Limitations of the gradient system).

Recently, however, in the field of research and diagnostics, there has been increased interest in more complex gradient pulse waveforms, in particular for tensor-weighted diffusion measurements, which promise “per design” access to new contrast characteristics, such as are described for example in the article by Szczepankiewicz et al., “Gradient Waveform Design for Tensor-Valued Encoding in Diffusion MRI,” J. Neurosc. Methods 348: p. 109007 (2021).

The increasing complexity of the gradient pulse waveforms employed here, however, presents great challenges to the preparation, planning and execution of such measurements.

In the processing of measurement protocols by a user, for example within the framework of tensor-weighted diffusion measurements with complex gradient pulse waveforms, the user is usually presented with a possible range of values in each case for each measurement parameter of a group of measurement parameters to be processed. In this case a respective range of values is divided for example into at least one of the categories “non-settable parameter values,” “conditionally settable parameter values,” and “unrestrictedly settable parameter values.” The division into such categories can be displayed to the user during processing of a measurement protocol in suitable form, for example color-coded, so that appropriate parameter values can be selected for the measurement parameters.

In this case, the assignment to a category A (“non-settable parameter value”) can be made when a parameter value of a processed measurement parameter assigned in this category A would lead to a measurement protocol that cannot be executed. Such parameter values can for example be blocked for the user, so that they cannot be selected by the user for the corresponding measurement parameter. Despite this, parameter values assigned in this category A can be displayed or otherwise brought to the attention of the user, for example for the case in which they could be able to be set, when the measurement protocol to be processed undergoes a suitable change at another points, for example corresponding change of at least one other measurement parameter of the measurement protocol, e.g. being in a dependent dependency relationship to the processed measurement parameter. Such dependencies of various measurement parameters on one another further increase the complexity of the processing of measurement protocols.

An assignment to a category B (“conditionally settable parameter value”) can be made when a parameter value of a processed measurement parameter assigned in this category B requires an automated, e.g. clearly defined change to a respective parameter value of at least one other measurement parameter than the processed measurement parameter to make the measurement protocol executable. The required automated change can then be made for example as soon as the user sets a parameter value for a processed measurement parameter assigned to category B, so that the adaptations needed for the executability of the measurement protocol are carried out automatically.

An assignment to a category C (“unrestricted”) can be made when a parameter value of a processed measurement parameter assigned in this category C has no influence on the executability of the processed measurement protocol. A parameter value of a processed measurement parameter assigned to this category C can be selected without the need for further adaptation.

Even during processing of a measurement protocol by a user, to be able to make such an assignment to at least one of the categories A, B or C, complex calculations are necessary. For instance, because, after each change of a parameter value of a measurement parameter for at least one other measurement parameter, but also for a plurality of other measurement parameters, the respective assignments of possible parameter values to one of the categories A (“not settable”), B (“conditionally settable”) and C (“unrestrictedly settable”) can change.

The calculations can in this case e.g. comprise the determination of a gradient amplitude G(t) necessary for a predetermined diffusion weighting (b-value).

In diffusion-weighted MR imaging, a so-called b-matrix B in the diffusion tensor model describes the diffusion-conditional acceptance of an MR signal S:

$$S = {S}_{0} exp ( - \underline{B} : \underline{D} ) .$$

Here, S₀ represents a signal amplitude without diffusion weighting, and D represents the diffusion tensor. For symmetrical tensors, the product B:D (dyadic product) in this case is defined as follows:

$$B : D = {b}_{xx} {D}_{xx} + {b}_{y y} {D}_{y y} + {b}_{z z} {D}_{z z} + 2 {b}_{xy} {D}_{xy} + 2 {b}_{xz} {D}_{xz} + 2 {b}_{y z} {D}_{y z}$$

Lastly, the diffusion tensor, also called the weighting tensor, describes a characteristic of the diffusion movement, for example an anisotropy due to a microscopic environment present in the examination object, and the b matrix describes a characteristic of the diffusion coding. A trace of the b matrix delivers a measure for the diffusion weighting, is invariant as regards rotations, and is also referred to as the b value:

$$b = Trace ( \underline{B} ) = {b}_{xx} + {b}_{y y} + {b}_{z z} .$$

The elements bᵢⱼ of the b matrix B are determined in accordance with the following calculation specification, wherein the integral over the total time of the diffusion coding, for example from an excitation by an RF excitation pulse for a time t=0 until the recording of the RF signal, which is acquired as measurement data, after expiry of the echo time TE, i.e. for t=TE):

$$\underline{B} = {}_{{0}_{}} {\int }^{{}_{TE}} {dt}^{′} q ( {t}^{′} ) {q}^{T} ( {t}^{′} )$$

With the gyromagnetic ratio γ and the q space vector q:

$$q ( {t}^{′} ) = γ {}_{{}_{0}} {\int }^{{}_{{t}^{′}}} {dt}^{″} G ( {t}^{″} )$$

with a course of a gradient G(t″) and with q^{T} as the transposed vector of the vector q.

It thus follows that the elements bᵢⱼ of the b matrix for any given gradient pulse sequence G(t)=G f(t)=G(fₓ(t), f_{y}(t), f_{z}(t)) can be calculated as follows:

$${b}_{ij} = {γ}^{2} {G}^{{2}_{}} {}_{{0}_{}} {\int }^{{}_{TE}} {dt}^{′} ( {}_{{}_{0}} {\int }^{{}_{{t}^{′}}} {dt}^{″} {f}_{i} ( {t}^{″} ) ) ( {}_{{}_{0}} {\int }^{{}_{{t}^{′}}} {dt}^{″} {f}_{j} ( {t}^{″} ) ) with i , j ∈ \{ x , y , z \}$$

For trapezoidal gradient pulse waveforms, gradient pulse waveforms, which can be assembled from trapezoidal gradient pulse waveforms, analytical considerations and simple approximations are known, which can carry out calculations of the elements bij of a b matrix during a planning of a measurement during a processing of parameter values of measurement parameters of measurement protocol sufficiently quickly. For complex, e.g. non-trapezoidal gradient pulse waveforms, these established techniques can however no longer be used on account of the greatly increased complexity.

The b matrix (i.e. the weighting tensor) is also to be determined when a measurement is being carried out, for example so that this can be stored as a DICOM parameter with image information obtained from the diffusion-weighted measurement data obtained. Because of the necessity of therefore being able to make the calculations in short time windows in real time during an ongoing measurement, a calculation effort necessary for the calculations for determination of the b matrix becomes of great importance. As a general rule, this is too high with known methods to be able to manage the required calculation for non-trapezoidal gradient pulse waveforms in real time. This is because determination of a b matrix (or of a b value), although it can be basically undertaken, for example based on a respective definition of a non-trapezoidal gradient pulse waveform step-by-step, for example on a time grid of a gradient unit of the magnetic resonance system, wherein all gradients to be switched relevant for the diffusion weighting should be considered, where necessary also inclusive of contributions from trapezoidal imaging gradients. Doing so during an interactive measurement planning and during a measurement being carried out for acquiring diffusion-weighted measurement data in real time, requires control computers with especially high computing power. Both the high energy outlay during operation of such a high-power computer and also the costs of such high-performance computers count against this solution.

Calculations for an assignment of parameter values of measurement parameters of a measurement protocol to one of the said categories can, in addition or as an alternative, comprise a check on the ability of a measurement to be carried out with the measurement protocol in respect of physiological limitations, e.g. peripheral of cardiological stimulations.

Analytical considerations and simple approximations are already known for trapezoidal pulse waveforms, which can make such calculations during planning of a measurement for a processing of parameter values of measurement parameters of a measurement protocol sufficiently quickly. For complex, e.g. non-trapezoidal gradient pulse waveforms however, these established techniques can once again no longer be used.

Approximations are already known with which a few gradient pulse waveforms can be approximated under specific conditions and be “enveloping” trapezoidal gradient pulse waveforms. For sine or cosine-like gradient pulse waveforms, an approximation through trapezoidal gradient pulse waveforms is to some extent easily possible, as long as the number of the halfwaves is sufficiently small, for example fewer than 100. Then, the aforementioned calculations are able to be carried out sufficiently quickly by means of such an approximation.

A method for trapezoidal gradient pulse waveforms is furthermore known for example from U.S. patent application publication no. US/20240295621, which during a measurement preparation, calculates an assignment of a trapezoidal gradient pulse waveform dependent on a maximum permitted slope S of a gradient amplitude G for specific pulse sequences, for example “monopolar”, “bipolar” or “oscillating” sequences s, and adapts the ramp durations of the trapezoidal gradient waveforms accordingly during measurement planning. This process is however once more not applicable to non-trapezoidal gradient pulse waveforms, because of their complex (and predetermined) form with constantly varying slope.

For more complex, e.g. non-trapezoidal, gradient pulse waveforms, which can be characterized/defined by several hundred or thousand data points, this approach is however no longer viable. What is more, the results of the calculations are as a general rule too conservative, since envelopes have a higher stimulation potential than the actual pulse waveforms.

It would basically be conceivable to ignore a few of the limitations previously mentioned, which can restrict an ability of a measurement for acquisition of diffusion-weighted measurement data from being carried out. And with regards to complying with physiological limitations, as a general rule monitoring mechanisms integrated into a magnetic resonance system could be relied on for this purpose. The disadvantage of such an approach is, however, that the ability of a measurement to be executed cannot be guaranteed at a start of the measurement, and thus an exceeding of these types of limitations established by such a monitoring mechanism during the measurement can lead during an ongoing measurement to a measurement being aborted.

Furthermore, after planning for a measurement has been carried out, a subsequent check on its ability to be executed, for example directly before a start of the measurement, would also be possible. Here, however, a user will often be forced to modify their measurement planning at very short notice, and possibly with a need for significant change to parameter values of measurement parameters to be set. In a clinical environment, this is not a practicable solution.

A further basic option for keeping computing efforts for the calculations for an assignment of parameter values to measurement parameters of a measurement protocol to be set low would be to provide protocols already tested beforehand as to their ability to be executed (with defined parameter values for measurement parameters to be set). Here, however, there is a lack of flexibility necessary in the clinical application for the design during planning of a measurement, in which parameter values of measurement parameters to be set of measurement protocols provided, for example in respect of a desired spatial resolution, a number of slices or of parameters determining a contrast such as an echo time TE, or a repetition time TR, are often to be optimized specifically for the individual case.

Basically, a downstream (for example one-time) check of an ability of a processed measurement protocol to be executed immediately before a start of the measurement is also conceivable. Here, however, a user will often be forced to modify their measurement planning at very short notice (and possibly with a necessity for significant change to parameter values of measurement parameters). In the clinical environment, this is hardly practicable.

A further option would be, even before a possible measurement, for example once during an installation of a magnetic resonance system, for measurement protocols tested for their ability to be executed (with defined measurement parameters) to be provided. Here, however, the flexibility necessary in the clinical application in the design of the measurement protocols (for example in respect of a spatial resolution, a number of slices or the parameters determining contrast such as an echo time TE or a repetition time TR) of individual measurements to be carried out is absent.

The object of the embodiments described herein thus address these issues and make possible for the user a simplified, where necessary interactive, planning of measurements with non-trapezoidal gradient pulse waveforms for diffusion encodings. The object is achieved by the various embodiments as described herein, including the claims.

A method for checking an ability to be executed of an acquisition of diffusion-weighted measurement data of an examination object with a magnetic resonance system when using a measurement protocol with non-trapezoidal gradient pulse waveforms for the diffusion encoding comprises the steps:
a) loading of a non-trapezoidal gradient pulse waveform,
b) loading of prepared characteristics for the loaded non-trapezoidal gradient pulse waveform,
c) receiving a condition that is to be fulfilled during the execution of the acquisition of the diffusion-weighted measurement data,
d) determining at least one relevant gradient amplitude for the gradient pulse waveform on the basis of the loaded characteristics and the condition,
e) checking an ability to be executed of an acquisition of diffusion-weighted measurement data of the examination object with the magnetic resonance system when using a measurement protocol with the non-trapezoidal gradient pulse waveform on the basis of the at least one relevant gradient amplitude determined.

The loading of prepared characteristics for at least one non-trapezoidal gradient pulse waveform of the measurement protocol allows a rapid check of an ability to be executed of an acquisition of diffusion-weighted measurement data of the examination object and a rapid assignment of possible parameter values for measurement data to be set of the measurement protocol to an ability to be executed of the measurement protocol on the magnetic resonance system while complying with the category specifying the loaded limit values. Through the assignment to the at least one category it is made easier for the user, during the planning of measurement parameter values to be carried out of a measurement parameter to be set to find a measurement protocol to be used and thus to obtain a measurement protocol able to be executed with the selected parameter values on the magnetic resonance system.

In this case, characteristics for any given pulse waveforms, without specific requirements for their design (for example a periodicity), can be prepared. There can be determination of characteristics of the non-trapezoidal on any given processing unit and at any given point in time before a measurement to be carried out, so that already during a commissioning of a magnetic resonance system, but also at any time after a commissioning, prepared characteristics for non-trapezoidal gradient pulse waveforms can be loaded, for example into a memory of the magnetic resonance system.

For example, the method described here allows a very fast calculation of diffusion weightings, e.g. b values and b matrixes, both during a measurement planning and when a measurement is being carried out. The method is applicable without restrictions for any given temporal sequences of trapezoidal and non-trapezoidal pulse waveforms within the framework of the measurement protocol, and is able to be adapted without the necessity for renewed preliminary calculations for any given rotations.

The method described here likewise allows a rapid determination of a maximum permissible gradient amplitude for checking compliance with physiological limit values, e.g. a maximum allowed stimulation, and in this way ensures an ability to be executed of a planned measurement, wherein again by the loading of the characteristics, which have already been calculated in preliminary calculations beforehand, for example during a preparation of the measurement, an especially rapid (interactive) measurement planning is made possible.

Overall, the method described herein thus simplifies and speeds up checking of an ability to be executed of a measurement for acquisition of diffusion-weighted measurement data with a non-trapezoidal gradient pulse waveform during planning of a measurement to be carried out with the magnetic resonance system.

A magnetic resonance system comprises a magnet unit, a gradient unit, a radio frequency unit, and a control facility with an assignment unit embodied for carrying out any of the methods described herein.

A computer program implements any of the methods described herein on a control facility when it is executed on the control facility. For example, the computer program comprises commands that, when executed by a control facility, for example a control facility of a magnetic resonance system, causes this control facility to carry out any of the methods as described herein. The control facility may be designed in the form of a computer.

The computer program can also be present here in the form of a computer program product, which is able to be loaded directly into a memory of a control facility, with program code means for carrying out any of the methods as described herein when the computer program product in is executed in the processing unit of the control facility.

A computer-readable memory medium comprises commands that, when executed by a control facility, for example a control facility of a magnetic resonance system, cause said facility to perform any of the methods as described herein.

The computer-readable memory medium can be embodied as an electronically-readable data medium, which comprises electronically-readable control information stored thereon, which comprises at least one computer program and is embodied such that, when the data medium is used in a control facility of a magnetic resonance system, it performs any of the methods as described herein.

The advantages and information specified with regard to the method also apply by analogy to the magnetic resonance system, the computer program product and the electronically-readable data medium.

### BRIEF DESCRIPTION OF THE DRAWINGS

Further advantages and details of the present disclosure emerge from the exemplary embodiments described below and also with the aid of the drawings. The examples given do not represent any restriction of the disclosure. In the figures:

FIG. 1 illustrates a schematic flow diagram of an example method for checking an ability to be executed of an acquisition of diffusion-weighted measurement data of an examination object with a magnetic resonance system when using a measurement protocol with non-trapezoidal gradient pulse waveforms for diffusion encoding, in accordance with one or more embodiments of the present disclosure;

FIG. 2 illustrates a schematic diagram of an example gradient with non-trapezoidal gradient pulse waveform GF on three axes Gx, Gy, Gz, in accordance with one or more embodiments of the present disclosure;

FIG. 3 illustrates a further schematic diagram of an example gradient with non-trapezoidal gradient pulse waveform GF on three axes Gx, Gy, Gz, in accordance with one or more embodiments of the present disclosure; and

FIG. 4 illustrates a schematic diagram of an example magnetic resonance system, in accordance with one or more embodiments of the present disclosure.

### DETAILED DESCRIPTION OF THE DISCLOSURE

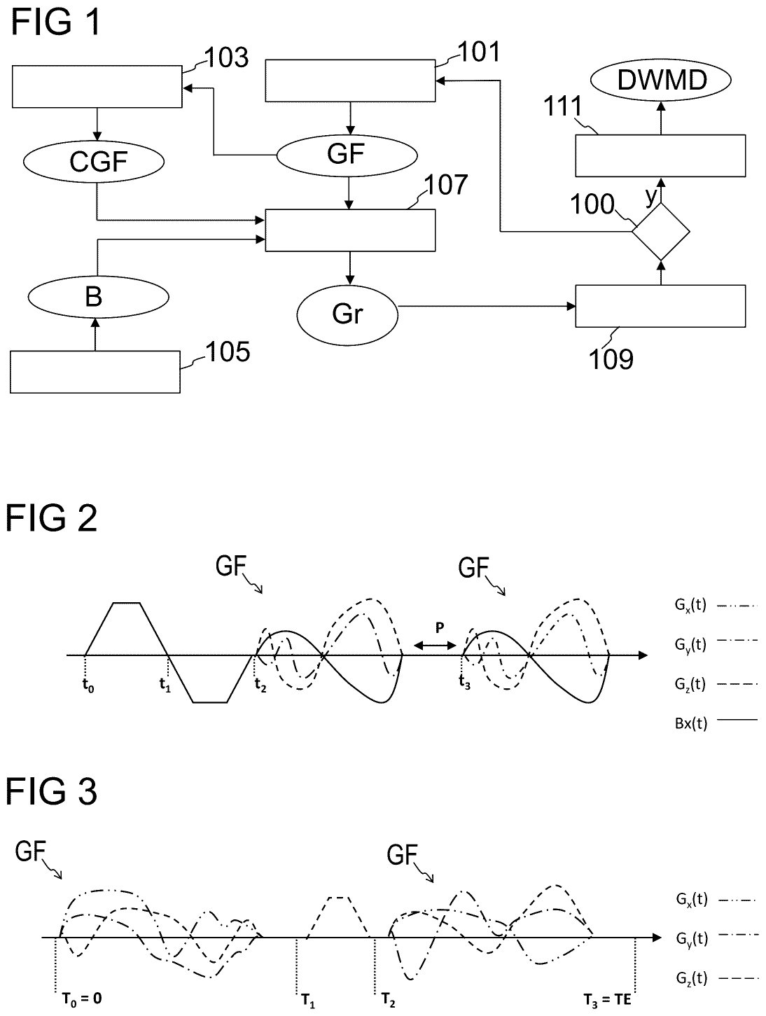

FIG. 1 illustrates a schematic flow diagram of an example method for checking an ability to be executed of an acquisition of diffusion-weighted measurement data of an examination object with a magnetic resonance system when using a measurement protocol with non-trapezoidal gradient pulse waveforms for diffusion encoding, in accordance with one or more embodiments of the present disclosure. Specifically, FIG. 1 is a schematic flow diagram of an example method for checking an ability to be executed of an acquisition of diffusion-weighted measurement data of an examination object with a magnetic resonance system when using a measurement protocol with non-trapezoidal gradient pulse waveforms for diffusion coding.

With respect to the flow diagram shown in FIG. 1, a non-trapezoidal gradient pulse waveform GF is loaded (block 101).

Prepared characteristics CGF for the loaded non-trapezoidal gradient pulse waveform GF are loaded (block 103). Such prepared characteristics CGF can for example comprise section-specific terms for a calculation of a diffusion variable, such as a diffusion tensor and/or a diffusion weighting (b value), and/or a maximum permitted gradient amplitude Gmax, e.g. assigned to an allowed stimulation of an examination object, e.g. for various ancillary conditions N, which have already been determined beforehand.

A condition B, which is to be fulfilled during the execution of the acquisition of the diffusion-weighted measurement data with the non-trapezoidal gradient pulse waveform GF is received (block 105). A condition can for example comprise a desired diffusion variable, such as a diffusion weighting and/or a maximum permitted stimulation of the examination object.

On the basis of the loaded characteristics CGF and the condition B, at least one gradient amplitude Gr relevant for the loaded gradient pulse waveform GF is determined (block 107).

For example, the received condition can comprise a maximum permitted stimulation, and e.g. at least one ancillary condition for the maximum permitted stimulation and a maximum gradient amplitude Gr determined, with which the permitted stimulation is not exceeded.

For checking the ability to be executed with regard to a maximum permitted stimulation loaded as a condition known stimulation models can be used. For example the SAFE model described in the article by Hebrank et al., “SAFE model—a new method for predicting peripheral nerve stimulations in MRI”, Proceedings of the 8th Annual Meeting of ISMRM, Denver, 2000, or a, a simpler although at the same time more conservative restriction of the maximum slope rate dB/dt at each point in time of the gradient pulse waveform GF, for example in accordance with standard IEC 60601-2-23, come into consideration as possible stimulation models.

Each of these models is capable, for any given course of a gradient amplitude G(t)=G f(t)=(fₓ(t), f_{y}(t), f_{z}(t)) of a gradient pulse waveform, to provide a statement A about whether the execution is permitted or not, which can be expressed in dummy code as:
A(G f(t), {Nᵢ})=true/false.

The condition can comprise for instance at least one ancillary condition for a maximum permitted stimulation and, for each ancillary condition, an associated maximum permitted stimulation.

An ancillary condition may e.g. be an ancillary condition from the group of an alignment of the axes of a gradient unit of the magnetic resonance system relative to the examination object, a stimulation type, and an operating mode to be selected.

In such a check of an ability to be executed with a stimulation model ancillary, conditions Nᵢ can be relevant. For example, an alignment of the axes x, y, z of the gradient unit 5 relative to an examination object, for example a patient, can find its way into the check.

Here, a support of a patient as examination object can for instance be interrogated as an ancillary condition Nᵢ, wherein for example a stomach, back, or side comes into consideration, and an orientation of the patient (head first or feet first).

An alignment of the main magnetic field relative to the axes x, y, z of the gradient unit may also be relevant as an ancillary condition Nᵢ, for example there are magnetic resonance systems with a main magnetic field running horizontally or vertically.

What is more, examination-specific ancillary conditions Nᵢ, such as for example operating modes, may be relevant for each measurement. Known here are various stages of allowed stimulations, for example as well as a “normal operating mode,” with a first probability of a stimulation and a “controlled enhanced operating mode,” in which higher stimulations of the examination object are permitted and stimulations with a higher probability occur, and which therefore may advantageously be confirmed by a user.

In addition or as an alternative a stimulation type can be relevant as an ancillary condition Nᵢ, wherein for example the stimulation types of peripheral nerve stimulations (PNS) and cardio stimulations (CNS) can be distinguished.

For non-trapezoidal gradient pulse waveforms, there can be a calculation of a stimulation potentials with one of the said models on a sufficiently narrow support point grid—for example 1 μs, 10 μs, 100 μs, etc., with the assumption of a constant gradient amplitude in the grid interval on each of the three axes.

Conversely, here a maximum permitted gradient amplitude for a gradient G(t) of the non-trapezoidal gradient pulse waveform GF can be determined, with which the execution is (just) still permitted, and which can be comprised by the loaded characteristics CGF. These type of calculations can be carried out beforehand, for example during a measurement preparation. Therefore, an increased computing effort caused by the complex non-trapezoidal gradient pulse waveforms plays a subordinate rule during the calculations.

In a simple exemplary embodiment, for a gradient with a non-trapezoidal gradient pulse waveform with a course of the gradient amplitude G(t)=G f(t) for each set {Nᵢ} of ancillary conditions during the measurement preparation with a search algorithm, that amplitude Gₘₐₓ is established with which the execution is just still permitted. To this end, for example an extensive search algorithm can be used, which could be represented in dummy code as:

| | |
|---|---|
| G = Gₗᵢₘᵢₜ | // System limit |
| dG = G_{inc} | // Search precision, for example 0.1mT/m |

While ( A(G * f(t), {Nᵢ}) != true)
G = G − G_{inc}
Gₘₐₓ = G

For stimulation models without time characteristic, i.e. stimulation models that do not take account of a history of previously switched gradient pulses, this procedure is already sufficient for establishing the maximum permitted gradient amplitude Gₘₐₓ for the selected set of ancillary conditions.

The SAFE model mentioned above checks a stimulation potential for example by processing (numerically) differentiated, axis-specific course of gradient amplitudes with different filter functions, and the results are combined into a temporal stimulation course. The latter is compared with limit values from which the ability to be executed is produced.

For these types of stimulation models with a time characteristic, it is necessary to make additional assumptions about previously switched gradient pulses, since the maximum gradient amplitudes are calculated beforehand, at a point in time at which details of the gradients used later within the framework of the measurement protocol for the imaging are not yet known.

For this, it can for example be assumed that immediately before the gradient with the non-trapezoidal gradient pulse waveform GF, which is used for diffusion encoding, a representative trapezoidal imaging gradient B (t) with a characteristic amplitude for the imaging (for example 50% of the hardware-side maximum) and rate of increase (for example 100% d of the hardware-side maximum) is applied. As an alternative, two or more consecutive imaging gradients Bₙ(t) with alternating amplitudes can be assumed: as a rule these have a higher stimulation potential and make sure in this way that there is a more reliable (more conservative) consideration of possible sequences of switched gradients of the imaging.

FIG. 2 illustrates a schematic diagram of an example gradient with non-trapezoidal gradient pulse waveform GF on three axes Gx, Gy, Gz, in accordance with one or more embodiments of the present disclosure. Specifically, FIG. 2 is a schematic diagram of a gradient with non-trapezoidal gradient pulse waveform GF on three axes Gx, Gy, Gz, wherein the course of the gradient amplitude with the gradient pulse waveform GF in the Gx direction is shown as a double dashed line, the course of the gradient amplitude with the gradient pulse waveform GF in the Gy direction as a single dashed and dotted line and the course of the gradient amplitude with the gradient pulse waveform GF in the Gz direction as a dashed line. Furthermore, to illustrate a possible imaging gradient Bx(t) is shown, which can be assumed to be switched directly before the gradient with the gradient pulse waveform GF. The imaging gradient Bx(t) shown, for example in a period of time from t0 and t1, has a positive polarity and in a directly following period of time from t1 to t2 has a negative polarity. An imaging gradient Bx(t) can for example involve a readout gradient train for recording of echo signals created by means of the measurement protocol by means of an echoplanar (EPI) recording technique.

Instead of defining a fixed rate of increase, as described above, for example in accordance with standard IEC 60601-2-23, in an initial step, in a known manner, for example by using a known stimulation model, a maximum rate of increase can be established, which after a predetermined number of alternating trapezoidal imaging gradients, produces a stimulation within the permitted limit values. With this preparation, it can be checked whether, after a representative number M (for example M=2) of imaging gradients, a predetermined non-trapezoidal pulse sequence is able to be executed, and the corresponding maximum permitted amplitude Gₘₐₓ will be established.

To this end for example, in the dummy code above, instead of A(G*f(t), {Nᵢ}) simply:

$$A ( {\sum }_{m = 1 … M} {B}_{m} ( t - {t}_{m - 1} ) + G * f ( t - {t}_{M} ) , \{ {N}_{i} \} )$$

Can be observed, wherein it is assumed that the imaging gradients Bₘ(t−tm−1) start in each case at point in time tₘ₋₁ and the last imaging gradient Bₘ(t−tm−1) ends at ty.

Establishing of maximum permitted gradient amplitudes Gmax can be carried out separately for different ancillary conditions {Nᵢ}. With the results, the procedure can be as follows for example:

For a stimulation type, e.g. PNS or CNS as the ancillary condition, the respective calculation can be carried out separately with PNS and CNS modeling, whereby maximum permitted gradient amplitudes G_{max,PNS}, G_{max,CNS} are determined. Since as a rule both limit values should be complied with the smaller of the two values can be comprised by the loaded characteristics, when planning a measurement, to be able to check an ability to be executed.

For an operating mode as ancillary condition, there can likewise be a separate execution of respective calculation, for example for operating modes “normal” (0th) and “increased in a controlled manner” (1st), whereby maximum permitted gradient amplitudes G_{max,0th}, G_{max,1st} will be determined. Both values can be comprised by the characteristics loaded, wherein they continue to have an assignment to the respective operating mode so that when, for example, through choice of a measurement protocol, where necessary a patient registration and/or a user input, an operating mode for a measurement to be carried out is defined, the corresponding value for the check of the ability to be executed can be used.

Also, for an alignment of the gradient axes relative to the examination object, e.g. to a patient as examination object, as an ancillary condition, there can be a separate execution of the respective calculation for different alignments ar, whereby maximum permitted gradient amplitudes {G_{max,ar}} are determined for various alignments ar. For this, a course of an amplitude G(t) of a gradient with a non-trapezoidal gradient pulse waveform can be written as a standardized course f(t) with a scaling G as G(t)=G f(t). The axes x, y, z of the gradient unit can for example be permutated in separate calculations, i.e. carried out with different assignments of the, e.g. standardized, non-trapezoidal gradient pulse waveforms f_{1/2/3} (t) for the axes x, y, z. The values obtained for {G_{max,ar}} can all be comprised (where necessary separately for each limit value and type) of loaded characteristic, so that, during a planning of a measurement, that value of {G_{max,ar}} for the checking of the ability to be executed can be included that is currently relevant for the measurement. Although this procedure needs more storage space, a largest possible maximum permitted gradient amplitude Gₘₐₓ from {G_{max,ar}} can be used for this. As an alternative, only the smallest of the values from {G_{max,ar}} can be comprised as maximum permitted gradient amplitude Gₘₐₓ=min{G_{max,ar}} by the loaded characteristics and used for the checking of the ability to be executed. This method of operation reduces storage space needed, reduces the complexity of the possible selection options, and allows checking of a measurement to be carried out independently of an actual support of the examination object.

Since it is not known a priori for which gradient axis Gx, Gy, Gz the combination of trapezoidal imaging gradients Bₘ(t−tm−1) and non-trapezoidal diffusion gradients of the gradient pulse waveform GF has the maximum stimulation potential, and thereby the smallest permitted Gₘₐₓ, there can be provision for assuming the application of imaging gradients Bₘ(t−tm−1) on all axes Gx, Gy, Gz simultaneously. However this—the SAFE model combines the stimulation potential of all axes-can lead to a disproportionately strong restriction of Gₘₐₓ.

It is therefore proposed that separate calculations be carried out with the assumption of a specific imaging axis in each case, so that the imaging gradient Bₘ(t−tm−1): can be written as:

$${B}_{x , m} ( t ) = ( {B}_{m} ( t ) , 0 , 0 ) , {B}_{y , m} ( t ) = ( 0 , {B}_{m} ( t ) , 0 ) , {B}_{z , m} ( t ) = ( 0 , 0 , {B}_{m} ( t ) ) .$$

The imaging gradient Bx(t) shown in FIG. 2 runs for example on the Gx axis.

With the same approach as before (without imaging gradients), separate maximum gradient amplitudes G_{max,x}, G_{max,y}, G_{max,z} can be determined in this way, of which at least the smallest (min{G_{max,x}, G_{max,y}, G_{max,z}}) can be loaded as maximum permitted gradient amplitude Gmax as characteristics of the gradient pulse waveform GF.

In the same way, a different polarity of the imaging gradients can be taken into account:

$${B}_{x , m}^{′} ( t ) = ( - {B}_{m} ( t ) , 0 , 0 ) , {B}_{y , m}^{′} ( t ) = ( 0 , - {B}_{m} ( t ) , 0 ) , {B}_{z , m}^{′} ( t ) = ( 0 , 0 , - {B}_{m} ( t ) ) ,$$

wherein, depending on the course of the non-trapezoidal gradient pulse waveform, the positive or the negative polarity of the imaging gradients can have the higher stimulation potential.

Where a sequence of a number of sections of non-trapezoidal gradient pulse waveforms is being used, for example before and after RF refocusing pulses to be radiated in, this can also already be taken into account beforehand similarly for planning of a measurement to be carried out, so that the statement A of the stimulation model can be written as follows:

$$A ( {Σ}_{m = 1 … N} {B}_{m} ( t - {t}_{m - 1} ) + G * {Σ}_{k = 1 … K} {f}_{k} ( t - {t}_{M + k - 1} ) , \{ {N}_{i} \} ) ,$$

wherein the sections each begin at point in time t_{M+k-1}.

Where temporal spacings between the sections are not defined during the measurement planning, for example because of different durations of refocusing modules depending on other measurement parameters of the measurement protocol, separate calculations with different temporal spacings P between two sections can be carried out, and at least the minimum results used as a limit value for the maximum permitted gradient amplitude Gmax for example. As a rule, a number of representative temporal spacings suffices here (for example P∈{0 ms, 5 ms, 10 ms, 20 ms}), of which the duration advantageously orients itself for example to a time characteristic of the stimulation model.

Shown by way of example in FIG. 2 is a sequence of two sections of non-trapezoidal gradient pulse waveforms GF with a temporal spacing P between the two sections.

Thus, during a measurement planning, at least one maximum permitted gradient amplitude of loaded characteristics CGF comprised by the non-trapezoidal gradient pulse waveform GF determined beforehand, can be used to check an ability to be executed of the planned measurement. For example, the check can comprise an assignment of parameter values of measurement parameters to be set of the measurement protocol used to at least one of the categories A, B, C, described above. With this, through the maximum permitted gradient amplitudes Gmax determined beforehand for example, permitted ranges of values of measurement parameters, for example of the b values, can be identified and where necessary characterized accordingly, wherein for example to assign b values that require higher gradient amplitudes than the maximum permitted gradient amplitude Gmax determined to the category “not settable.” In this case, no complex stimulation considerations are necessary during the measurement planning, since these have already been carried out beforehand, which makes possible a rapid and interactive operation.

There can be provision for making known to a user the presence of a limitation of possible parameter values, for example as a notification during reading in of the non-trapezoidal gradient pulse waveform GF or as a “tooltip” during the measurement planning. The user can use this as an opportunity to adapt the non-trapezoidal gradient pulse waveforms GF.

A maximum permitted gradient amplitude Gmax established can furthermore be scaled with a safety factor S<1 (for example S=0.90, S=0.95, etc.). In this way, the probability of measurement interruptions is reduced, e.g. in cases in which a pre-calculation carried out for determining the maximum permitted gradient amplitude Gmax has not detected a specific measurement protocol with an especially high stimulation potential to be used.

In addition, other approaches to checking stimulation limits can be carried out in combination. For example, for reduction of the stimulation potential, an amplitude of diffusion gradients with non-trapezoidal gradient pulse waveform GF can already be limited beforehand, while the stimulation potential of imaging gradients, for example of an echoplanar readout gradient train, is only checked at the start of the measurement. In this way, the task of stimulation monitoring can be achieved in two steps: In the preparation an adapted maximum permitted gradient amplitude Gmax of the diffusion gradients is already taken care of, even in the measurement planning an ability to be executed within given stimulation limits comprised by loaded conditions is provided. This restricts the possible scope for solution in a downstream check of the imaging gradients during the start of the measurement in such a way that, in the case of existing limit values being exceeded, a suitable choice of changes to the parameter values of measurement parameters to be set, for example longer ramps of the EPI readout gradients, can quickly be suggested to a user.

Gradient pulse waveforms GF, which are defined on axes Gx, Gy, Gz, can be transformed by a suitable rotation into another coordinate system, for example from a logical coordinate system, in which there has been planning of a desired image volume ROI (region of interest), into a physical coordinate system, for example of axes x, y, z of the gradient unit 5 of the magnetic resonance system 1, or for direction assignments for desired diffusion encoding directions. For rotations of the non-trapezoidal gradient pulse waveforms, it is to be noted that their stimulation potential can change significantly through the rotation. In more complex stimulation models with a temporal characteristic (for example the SAFE model), it is thus sensible already to take account of rotations during the pre-calculation. The calculations needed for this can be carried out extensively for any given rotations. In the three-dimensional space, any given rotation can be described by three independent parameters, for example the Euler angle. To take account of any given rotations the calculations described above can be carried out with stimulation models for a plurality of discrete angle combinations {αᵢ, βⱼ, γₖ} with a defined number of steps I, J, K in each case: αᵢ=2π*i/I, βⱼ=2π*j/J, γₖ=2π*k/K. From these results, at least the smaller value of the maximum permitted gradient amplitudes obtained in this way for the various rotations then be included as the maximum permitted gradient amplitude of the loaded characteristics. As an alternative, a more restricted and thereby less complex calculation can be carried out for various rotations. The requirement for this option is that a) the non-trapezoidal gradient pulse waveforms GF are described in physical coordinates of the axes x, y, z of a gradient unit, and b) direction assignments of the diffusion encoding (with associated rotation matrixes Rₘ) are already known during the measurement preparation. In this case, it is sufficient to carry out the calculations described above with the transformed pulse waveforms G′ₘ(t)=GRₘf(t) in each case just for the necessary direction assignments Rₘ. Then, from these results, at least the smallest value of the maximum permitted gradient amplitudes obtained in this way for the various rotations are included as maximum permitted gradient amplitude by the characteristics.

For the same non-trapezoidal gradient pulse waveforms GF on all axes Gₙ(t)=G f(t) Vₙ with the direction vectors Vₙ=(V_{n,x}, V_{n,y}, V_{n,z}) it can be sufficient, in the measurement preparation, to restrict oneself to a consideration of the case of maximum stimulations. For this purpose, for example a “worst case” can be assumed. In the usual simulation models, for example the SAFE model, a maximum stimulation potential occurs for direction vectors V with |V|=1 when the gradient activity occurs entirely on one axis, i.e. V=(1, 0, 0), V=(0, 1, 0) or V=(0, 0, 1). Thus, it is sufficient to consider precisely these cases in the measurement preparation. As an alternative, restricted calculations can also be carried out here, wherein the requirement is that a) the non-trapezoidal gradient pulse waveform is described in physical coordinates of the axes x, y, z of the gradient unit, and b) the direction vectors Vₙ are already known during the measurement planning. The calculations described above are then carried out with the transformed pulse waveforms Gₙ(t)=G f(t) Vₙ in each case and once again at least the smallest of maximum permitted gradient amplitudes established in this way is included in the loaded characteristics.

There can be provision, during determination of maximum permitted gradient amplitudes, for taking into account not only stimulation limitations, but also, at the same time or successively, limitations of the gradient unit. Here, e.g. maximum slew rates on each of the axes x, y, z able to be achieved with the gradient unit come into consideration. Thus, as well as the statement A (for checking the stimulation) a further statement B (for checking the slew rates) is to be taken into account, which is able to be expressed in dummy code as:

| B(G f(t)) = true / false | |
|---|---|
| G = Gₗᵢₘᵢₜ | // System limit |
| dG = G_{inc} | // Search precision, for example 0.1mT/m |

While ( A(G * f(t), {Nᵢ}) != true) && (B(G * f(t) != true)
G = G − G_{inc}
Gₘₐₓ = G

A simple check could appear as follows in dummy code:

| | |
|---|---|
| | B: max(\|Sᵢ(t)\| ≤ S_{i,max} i ∈ {x, y, z} |
| With | S(t) = G * df(t) / dt |

Where standardized gradient courses f (t) of the non-trapezoidal gradient pulse waveform are present on a sufficiently fine grid, for example with a grid of Tᵣₐₛₜₑᵣ=1μ, 10 μs or 100 μs, the derivation to be calculated here can be established numerically:

$$S ( {t}_{k} ) = G * ( f ( {t}_{k + 1} ) - f ( {t}_{k} ) ) / {T}_{g r i d}$$

A received condition can comprise a desired b value and a gradient amplitude needed for achieving the desired b value with the gradient pulse waveform can be determined as the relevant gradient amplitude.

The gradient pulse waveform GF can be broken down into, e.g. temporally non-overlapping, sections and the loaded characteristics for the sections comprise section-specific terms for a determination of elements of a b matrix with the desired b value. In order to check whether individual sections i are overlapping in time, during the planning and/or carrying out of the measurement, it can simply be checked automatically for each standardized course fᵢ(t), whether fᵢ(t)=0 applies, for t<Tᵢ and t>Tᵢ₊₁. If this is not the case, an error message can be displayed and/or parameter values that would lead to an overlap can be assigned to “not settable” and where necessary marked accordingly.

FIG. 3 illustrates a further schematic diagram of an example gradient with non-trapezoidal gradient pulse waveform GF on three axes Gx, Gy, Gz, in accordance with one or more embodiments of the present disclosure. Specifically, FIG. 3 is a schematic diagram of a gradient with non-trapezoidal gradient pulse waveform GF on three axes Gx, Gy, Gz, wherein, as in FIG. 2 the course of the gradient amplitude with the gradient pulse waveform GF in the Gx direction is shown as a double dotted and dashed line, the course of the gradient amplitude with the gradient pulse waveform GF in the Gy direction as a single dotted and dashed line and the course of the gradient amplitude with the gradient pulse waveform GF in Gz direction as a dashed line. There can be a segmentation of the gradient pulse waveform GF at points in time T0, T1, T2 and T3 (=TE), as described below.

A preparation of section-specific terms as characteristics CGF of the gradient pulse waveform GF can comprise a formation of a standardized course f (t) of the gradient amplitude of the gradient pulse waveform GF.

A gradient pulse waveform GF can for example, for the sake of simplicity, be broken down into two sections, so that a gradient pulse sequence G(t) arising from the segmentation consisting of two gradients, 1(t) and G2(t), can be defined as follows for any given gradient pulse sequence G(t)

$$G ( t ) = {G}_{1} ( t ) = {Gf}_{1} ( t ) for 0 \leq t < {T}_{1} G ( t ) = {G}_{2} ( t ) = G {f}_{2} ( t ) for {T}_{1} \leq t < TE \to {b}_{i j} = {γ}^{2} {{G}^{2}}_{0} {\int }^{TE} {dt}^{′} {(}_{0} {\int }^{{t}^{′}} {dt}^{″} {f}_{i} ( {t}^{″} ) ) {(}_{0} {\int }^{{t}^{′}} {dt}^{″} {f}_{j} ( {t}^{″} ) ) = {γ}^{2} {G}^{2} {(}_{0} {\int }^{T 1} {dt}^{′} {(}_{0} {\int }^{{t}^{′}} {dt}^{″} {f}_{i} ( {t}^{″} ) ) {(}_{0} {\int }^{{t}^{′}} {dt}^{″} {f}_{j} ( {t}^{″} ) ) + {}_{T 1} {\int }^{TE} {dt}^{′} {(}_{0} {\int }^{{t}^{′}} {dt}^{″} {f}_{i} ( {t}^{″} ) ) {(}_{0} {\int }^{{t}^{′}} {dt}^{″} {f}_{j} ( {t}^{″} ) ) )$$

The first term (for t′∈[0, T₁] gilt) represents just the b matrix elements of the first section:

$${b}_{i j , 1} = {γ}^{2} {{G}^{2}}_{0} {\int }^{T 1} {dt}^{′} {(}_{0} {\int }^{{t}^{′}} {dt}^{″} {f}_{i} ( {t}^{″} ) ) {(}_{0} {\int }^{{t}^{′}} {dt}^{″} {f}_{j} ( {t}^{″} ) )$$

The second term can cleverly be broken down further:

$${b}_{i j} = {b}_{i j , 1} + {γ}^{2} {G}^{2} {}_{T 1} {\int }^{TE} {dt}^{′} {(}_{0} {\int }^{{t}^{′}} {dt}^{″} {f}_{i} ( {t}^{″} ) ) {(}_{0} {\int }^{{t}^{′}} {dt}^{″} {f}_{j} ( {t}^{″} ) ) ) = {b}_{i j , 1} + {γ}^{2} {G}^{2} {}_{T 1} {\int }^{TE} {dt}^{′} {(}_{0} {\int }^{T 1} {dt}^{″} {f}_{i} ( {t}^{″} ) ) + {}_{T 1} {\int }^{{t}^{′}} {dt}^{″} {f}_{i} ( {t}^{″} ) ) {(}_{0} {\int }^{T 1} {dt}^{″} {f}_{j} ( {t}^{″} ) + {}_{T 1} {\int }^{{t}^{′}} {dt}^{″} {f}_{j} ( {t}^{″} ) )$$

With M_{i,1=0}∫^{T1}dt″fᵢ(t″) and M_{j,1=0}∫^{T1}dt″fⱼ(t″) the following is obtained:

$${b}_{i j} = {b}_{i j , 1} + {γ}^{2} {G}^{2} {}_{T 1} {\int }^{TE} {dt}^{′} ( {M}_{i , 1} {M}_{j , 1} + {M}_{i , 1} {}_{T 1} {\int }^{{t}^{′}} {dt}^{″} {f}_{j} ( {t}^{″} ) + {M}_{j , 1} {}_{T 1} {\int }^{{t}^{′}} {dt}^{″} {f}_{i} ( {t}^{″} ) {}_{T 1} {\int }^{{t}^{′}} {dt}^{″} {f}_{j} ( {t}^{″} ) {}_{T 1} {\int }^{{t}^{′}} {dt}^{″} {f}_{j} ( {t}^{″} ) )$$

The last term (for which t′∈[T₁, TE] applies) represents just the b matrix elements of the second section:

$${b}_{ij , 2} = {γ}^{2} {{G}^{2}}_{T 1} {\int }^{TE} {dt}^{′} {(}_{T 1} {\int }^{{t}^{′}} {dt}^{″} {f}_{i} ( {t}^{″} ) ) {(}_{T 1} {\int }^{{t}^{′}} {dt}^{″} {f}_{j} ( {t}^{″} ) )$$

With K_{i,2=T1}∫^{TE}dt′_{T1}∫^{t′}dt″fⱼ(t″) and K_{j,2=T1}∫^{TE}dt′_{T1}∫^{t′}dt″fⱼ(t″) this produces:

$${b}_{i j} = {b}_{i j , 1} + {b}_{ij , 2} + {γ}^{2} {G}^{2} ( ( T E - {T}_{1} ) {M}_{i , 1} {M}_{j , 1} + {M}_{i , 1} {K}_{i , 2} + {M}_{j , 1} {K}_{i , 2} )$$

The decisive point in this segmentation is that each of these terms only still relates to one of the two sections. Thus, it is possible, in the measurement preparation, to carry out section-specific pre-calculations independently of one another, and to use results of these pre-calculations that comprise characteristics CGF of gradient pulse waveform GF during a planning and/or a carrying out of a measurement for calculation of a combined b matrix, which no longer require great computing effort.

In this case, for a first section 1, the section-specific terms b_{ij,1}, M_{i,1}, M_{j,1}, and for a second section 2 the section-specific terms b_{ij,2}, K_{i,2}, K_{j,2}, can already be calculated in pre-calculations.

It is of no significance in this case whether G₁(t) and/or G₂(t) are trapezoidal or non-trapezoidal. For gradients with a non-trapezoidal gradient pulse waveform the calculations can be undertaken on a sufficiently narrow support point grid—for example 1 μs, 10 μs, 100 μs, etc., with the assumption of a constant gradient amplitude in the grid interval on each of the three axes: The integrations are then simplified to summations. Since the pre-calculations are only needed once during the measurement preparation, the increased computing effort associated with this only plays a subordinate role.

The approach can be expanded in any given way to more than two sections: for this the sections can be considered successively and the respective pre-calculations accumulated. For example the gradient pulse waveform GF in FIG. 3 can also be subdivided into three sections with:

$$\begin{matrix}G ( t ) = {G}_{1} ( t ) = G {f}_{1} ( t ) for 0 \leq t < {T}_{1} \\ G ( t ) = {G}_{2} ( t ) = G {f}_{2} ( t ) for {T}_{1} \leq t < {T}_{2} \\ G ( t ) = {G}_{3} ( t ) = G {f}_{3} ( t ) for {T}_{2} \leq t < TE\end{matrix}$$

The pre-calculation for the sections 1 and 2 can be undertaken in a similar way to that described above, wherein TE is replaced by T₂. The following is obtained: b_{ij,1&2}: calculation as described previously (TE is replaced by T₂)

$${{M}_{i / j , 1 \& 2} : {M}_{i / j , 1 \& 2} {=}_{0} {\int }^{T 2} {dt}^{″} {f}_{i / j} ( {t}^{″} ) =}_{0} \text{} {\int }^{T 1} {dt}^{″} {f}_{i / j} ( {t}^{″} ) {+}_{T 1} \text{} {\int }^{T 2} {dt}^{″} {f}_{i / j} ( {t}^{″} ) = {M}_{i / j , 1} + {M}_{i / j , 2}$$

For the new section 3, the terms b_{ij,3}, K_{i,3}, K_{i,3} can be precalculated, resulting in:

$$\to {b}_{i j} = {b}_{i j , 1 \& 2} + {b}_{ij , 3} + {γ}^{2} {G}^{2} ( ( TE - {T}_{2} ) {M}_{i , 1 \& 2} {M}_{j , 1 \& 2} + {M}_{i , 1 \& 2} {K}_{i , 3} + {M}_{j , 1 \& 2} {K}_{i , 3} )$$

It should be pointed out that a complete pre-calculation of the b matrix elements during the measurement preparation is not possible. The reason for this on the one hand is that the spacing of the sections can change during the measurement preparation, for example the duration of a refocusing module can change between two sections, for example between section 1 and section 2, depending on parameter values set for the measurement protocol. On the other hand, the contributions of imaging gradients to the b matrix, for example of spoiler or slice encoding gradients, can vary depending on parameter values set for measurement parameters to be set of the measurement protocol. The previously described breaking down and dividing up of the computing operations is thus essential for the interactive measurement planning.

When the pre-calculations are carried out on standardized gradient waveforms f (t), the b matrix elements for any given actual gradient amplitudes G are able to be determined from this in a simple way by corresponding scaling of the results.

The rapid determination of the b matrixes described here is advantageously able to be applied here both in the measurement planning, e.g. for a fast calculation of a gradient amplitude necessary for a predetermined b value, and also while a measurement is being carried out, for example for a rapid calculation of all b matrix elements for an image currently being measured, e.g. for storage in the DICOM header of the current image and/or a use for example for diffusion tensor calculations. Thus, on the basis of loaded characteristics, diffusion tensors employed during the measurement can be calculated. The key to this is the clever breaking down of the calculation specification, with which all time-consuming calculation steps can already be carried out once during the measurement preparation.

During the measurement planning, it is not necessary as a rule to take into account rotations of the non-trapezoidal gradient pulse waveforms GF. The reason for this is that, during the measurement planning, just the b value (i.e. the trace of the b matrix) is relevant for assigning parameter values, for example into areas, at least of a category “non-settable,” “conditionally settable,” or “unrestrictedly settable.” The trace of the b matrix is invariant as regards rotations R: Trace (R B R⁻¹)=Trace (B).

During the carrying out of the measurement however rotations of the non-trapezoidal gradient pulse waveforms GF into another, for example physical coordinate system and/or for a direction assignment, should be taken into account. For diffusion tensor calculations (and for the storage of data in DICOM format) all elements bij of the b matrix should be known. The calculation of the b matrix element while taking into account a rotation R is easily possible through a transformation (tensor or vector rotation) of the pre-calculated value. The following is produced:

$$\begin{matrix}[ {b}_{i j}^{′} ] = {\underline{B}}^{′} = \underline{R} \underline{B} {\underline{R}}^{- 1} \\ [ {M}_{i}^{′} ] = {M}^{′} = \underline{R} M \\ [ {K}_{i}^{′} ] = {K}^{′} = \underline{R} K\end{matrix}$$

With the transformed variables b′ᵢⱼ, M′ᵢ, K′ᵢ (i, j∈{x′, y′, z′}), the steps described previously for combination of contributions of a number of sections—now while taking into account the rotation—can be carried out unchanged.

For the same, non-trapezoidal gradient pulse waveforms GF on all axes Gₙ(t)=G f(t) Vₙ with the direction vectors Vₙ=(V_{n,x}, V_{n,y}, V_{n,z}) the elements of the b-Matrix are determined in the same way. In this case a rotation matrix Rn can be determined in such a way that it transfers a single-axis gradient pulse waveform assumed in the pre-calculation, for example on the Gx axis: Gₓ(t)=G f(t) (1, 0, 0), just into the desired direction assignment of the diffusion direction:

$${G}_{n} ( t ) = {R}_{n} {G}_{x} ( t ) , with {R}_{n} = ( \begin{matrix}{v}_{n , x} , & {v}_{n , y ,} & {v}_{n , x} \\ 0 , & 0 , & 0 \\ 0 , & 0 , & 0\end{matrix} )$$

In the calculation of b matrixes, combinations consisting of sections with trapezoidal and non-trapezoidal gradient pulse waveforms can be taken into account. To do this, for non-trapezoidal gradient pulse waveforms the described pre-calculations can be applies to grid intervals. A precise form of trapezoidal gradients to be switched is usually only known during the measurement planning (imaging gradients change their form and amplitude depending on resolution parameters). Associated b matrix elements b_{ij,trap} can however, due to the part linear shape, be established quickly with known methods. This also applies to the further variables M_{i,trap} and K_{i,trap} that might be needed for combination with non-trapezoidal sections.

Through the breaking down of the gradient pulse waveform into sections and the breaking down described for a determination of the computing operations needed for the diffusion values into time-consuming sections that are carried out once during the measurement preparation, and into quick to manage sections, which are to be calculated repeatedly during the measurement planning and/or measurement execution, the planning of the measurement and assignment of parameter values from measurement parameters of the measurement protocol into the described categories A, B and C is speeded up and simplified.

If RF pulses are radiated in between the sections, then their effect in the successive calculation of the b matrix for example can be taken into account as follows. After radiating in an RF excitation pulse, all accumulated variables (bᵢⱼ=0, M_{i/j}=0) up to the time of the radiating in can be reset. N After radiating in an RF refocusing pulse, for example for creation of a spin echo, the gradient amplitudes in all following sections can be inverted. With multiple refocusings, an alternating inversion of the polarities in accordance with (−1)ⁿ can accordingly occur. After RF pulses have been radiated in for storage, for example of a longitudinal magnetization, for example for creation of a stimulated echo, until the next RF recovery pulse is radiated in, all following sections of the gradient pulse waveform are ignored, since these, the stored state of the magnetization, have no influence on the diffusion encoding. After an RF recovery pulse is radiated in, from that time on all following sections of the gradient pulse waveform can be taken into account again, and even after inversion of the gradient amplitudes. Lastly, the effect of a pair consisting of RF storage and RF recovery corresponds to that of an RF refocusing pulse, wherein however any gradient activity between storage and recovery still has no effect on the magnetization.

As is generally known, imaging gradients of which the influence is small on the b matrix (for example a slice selection gradient and an associated slice rephasing gradient, which are applied directly after one another), are ignored for further speeding up of the calculation. Other imaging gradients with significant influence can be taken into account, for example spoiler gradients (for suppression of undesired signal paths). That relates e.g. to those gradients for which the 0th moment generated by them is only compensated for at a later time. This applies for example for a pair of spoiler gradients with a first spoiler gradient before an RF storage pulse and a second spoiler gradient after an RF recovery pulse.

An ability to be executed of an acquisition of diffusion-weighted measurement data DWMD of the examination object with the magnetic resonance system 1 while using a measurement protocol with the non-trapezoidal gradient pulse waveform GF is checked on the basis of the at least one relevant gradient amplitude Gr determined (query 100).

If the outcome of the check is a positive result (query 100, y), a measurement for acquisition of diffusion-weighted measurement data DWMD with a diffusion encoding is carried out with the gradient pulse waveform GF (block 111). A positive result is present when values can be found for all measurement parameters of the measurement protocol parameters of the measurement used, with which the measurement is able to be carried out under all required boundary conditions.

If the outcome of the check is a negative result, a gradient amplitude of the diffusion gradient to be switched with the non-trapezoidal gradient pulse waveform GF can be reduced, or other parameter values of measurement parameters, for example possible b values of the measurement protocol are adjusted, e.g. may be assigned to one of the categories A, B and C mentioned above, so that where necessary a set of parameter values of the measurement parameters of the measurement protocol can be found, that leads to the measurement being able to be carried out. As an alternative for example another non-trapezoidal gradient pulse waveform GF can be loaded and the method can be run once again with this or adaptations can be made to suitable other parameter values of measurement parameters of the measurement protocol or at least suggested.

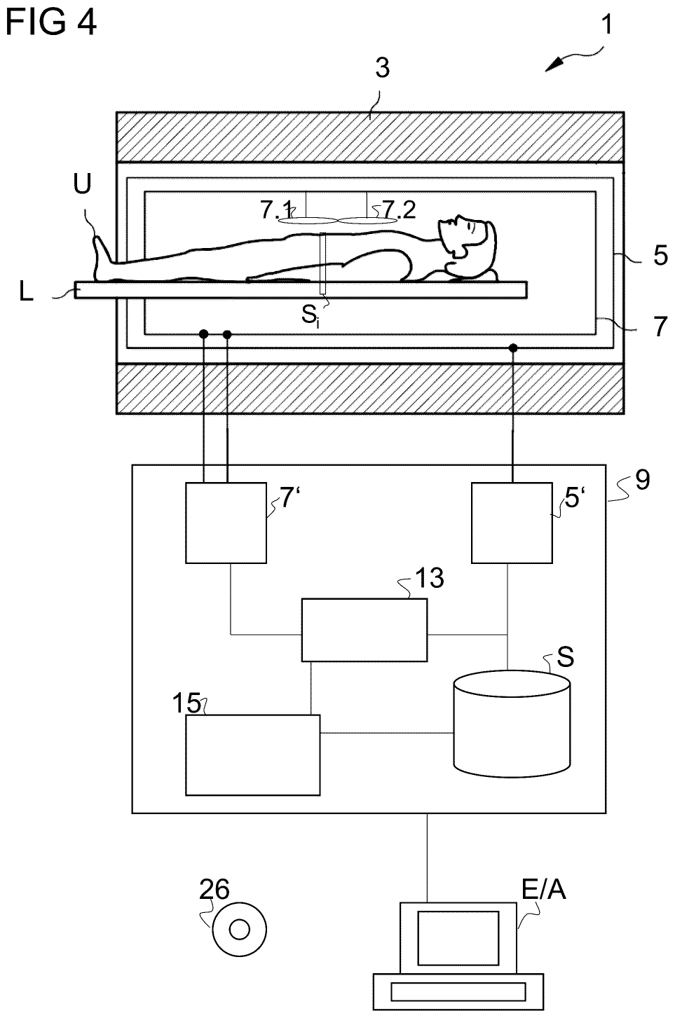

FIG. 4 shows a schematic of a magnetic resonance system 1. Said system comprises a magnet unit 3 for creation of a basic magnetic field, a gradient unit 5 for creation of the gradient fields, a radio frequency unit 7 for radiating in and for receiving radio frequency signals and a control facility 9 embodied for carrying out any of the methods as discussed herein.

FIG. 4 illustrates a schematic diagram of an example magnetic resonance system, in accordance with one or more embodiments of the present disclosure Specifically, in FIG. 4, these subunits of the magnetic resonance system 1 are shown as rough schematics. The radio frequency unit 7 (also referred to herein as RF circuitry) can consist of a number of subunits and for example comprise a number of coils. For instance, the radio frequency unit 7 can comprise a body coil, which is integrated permanently into the magnetic resonance system 1, and in its turn for example can comprise two antenna elements 7.1 and 7.2. The radio frequency unit 7 can furthermore comprise one or more different local coils 7*, which can be embodied either just for sending radio frequency signals or just for receiving the triggered radio frequency signals or for both, and for its part can comprise a number of antenna elements and associated coil channels.

For examination of an examination object U, for example of a patient or also of a phantom, said object can be brought on a couch L into the magnetic resonance system 1 in its measurement volume. The slices S1 or S2 represent exemplary target volumes of the examination object, from which echo signals are recorded and can be acquired as measurement data.

The control facility 9 (also referred to herein as a controller, control computer, or processing circuitry) is used for control of the magnetic resonance system 1 and may e.g. control the gradient unit 5 (also referred to herein as gradient circuitry) by means of a gradient controller 5′ (also referred to herein as gradient control circuitry) and the radio frequency unit 7 by means of a radio frequency send/receive controller 7′ (also referred to herein as RF control circuitry). The radio frequency 7 can comprise a number of channels here on which signals can be sent or received.

The radio frequency unit 7 is responsible, together with its radio frequency send/receive controller 7′, for the creation and radiating in (sending) of a radio frequency alternating field für manipulation of the spins in a region to be manipulated (for example in slices S to be measured) of the examination object U. In this case, the mid frequency of the radio frequency alternating field, also referred to as the BI field, is set as a general rule so that it lies close to the resonant frequency of the spins to be manipulated. Deviations of the mid frequency from the resonant frequency are referred to as off resonance. For creation of the B1 field, in the radio frequency unit 7 currents are applied to the RF coils controlled by means of the radio frequency send/receive controller 7′.

The control facility 9 furthermore comprises a planning unit 15 (also referred to herein as planning circuitry) for carrying out the check as described in accordance with the embodiment's herein. Overall, the control facility 9 is embodied for carrying out any of the methods as discussed herein.

A processing unit 13 (also referred to herein as processing circuitry) comprised by the control facility 9 is embodied for carrying out all processing operations needed for the measurements and determinations needed. Intermediate results and results needed for this or established here can be stored in a memory unit S of the control facility 9. The units shown are to be not absolutely to be understood here as physically separate units, but merely represent a subdivision into logical units, which however can also be realized for example in fewer or also in just one single physical unit.

Control commands can be directed to the magnetic resonance system, for example by a user, and/or results, such as image data for example, displayed to the control facility 9 via an input/output facility E/A of the magnetic resonance system 1.

A method described herein can also be present in the form of a computer program, which comprises commands that carry out any of the methods as discussed herein via the control facility 9. Likewise, a computer-readable storage medium can be present, which comprises commands that, when executed by a control facility 9 of a magnetic resonance system 1, cause said system to carry out any of the methods as discussed herein.

Independent of the grammatical term usage of a specific person-related term, individuals with male, female or other gender identities should be included within the term.

Additionally, the various components described herein may be referred to as “facilities,” or “units.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such facilities, units, etc., as applicable and relevant, may alternatively be referred to herein as “circuitry,” “controllers,” “processors,” or “processing circuitry,” or alternatively as noted herein.

What is claimed is:

1. A method for verifying that diffusion-weighted measurement data of an examination object is capable of being acquired via a magnetic resonance system when using a measurement protocol with non-trapezoidal gradient pulse waveforms for diffusion encoding, the method comprising:
loading a non-trapezoidal gradient pulse waveform;
loading predetermined characteristics for the loaded non-trapezoidal gradient pulse waveform;
receiving a condition that is satisfied when the diffusion-weighted measurement data is acquired;
determining at least one relevant gradient amplitude for the loaded non-trapezoidal gradient pulse waveform based upon the loaded predetermined characteristics and the condition; and
verifying that the diffusion-weighted measurement data is capable of being acquired when using the measurement protocol with the loaded non-trapezoidal gradient pulse waveform based upon the at least one determined relevant gradient amplitude.

2. The method as claimed in claim 1, wherein the condition comprises a desired b value and a gradient amplitude to achieve the desired b value using the loaded non-trapezoidal gradient pulse waveform.

3. The method as claimed in claim 2, wherein the loaded non-trapezoidal gradient pulse waveform is separated into temporally non-overlapping sections, and
wherein the loaded predetermined characteristics comprise section-specific terms for a determination of elements of a b matrix with the desired b value.

4. The method as claimed in claim 3, wherein the section-specific terms comprise a formation of a standardized course of the gradient amplitude of the loaded non-trapezoidal gradient pulse waveform.

5. The method as claimed in claim 1, wherein the condition comprises (i) a maximum permitted stimulation, (ii) at least one ancillary condition for the maximum permitted stimulation, and (iii) a maximum gradient amplitude for which the maximum permitted stimulation is not exceeded.

6. The method as claimed in claim 5, wherein the condition further comprises, for each ancillary condition, an associated maximum permitted stimulation.

7. The method as claimed in claim 6, wherein the at least one ancillary condition comprises one or more of an alignment of axes of a gradient unit of the magnetic resonance system relative to the examination object, a stimulation type, or an operating mode to be selected.

8. The method as claimed in claim 1, wherein when the outcome of the verification is positive, executing a measurement for acquisition of diffusion-weighted measurement data using a diffusion encoding with the loaded non-trapezoidal gradient pulse waveform.

9. The method as claimed in claim 8, further comprising:
calculating, during the measurement and based upon the loaded predetermined characteristics, diffusion tensors used for the measurement.

10. A magnetic resonance system, comprising:
a patient receiving area configured to receive an examination object for a magnetic resonance examination; and
a controller configured to verify that diffusion-weighted measurement data of the examination object is capable of being acquired via the magnetic resonance system when using a measurement protocol with non-trapezoidal gradient pulse waveforms for diffusion encoding by:
loading a non-trapezoidal gradient pulse waveform;
loading predetermined characteristics for the loaded non-trapezoidal gradient pulse waveform;
receiving a condition that is satisfied when the diffusion-weighted measurement data is acquired;
determining at least one relevant gradient amplitude for the loaded non-trapezoidal gradient pulse waveform based upon the loaded predetermined characteristics and the condition; and
verifying that the diffusion-weighted measurement data is capable of being acquired when using the measurement protocol with the loaded non-trapezoidal gradient pulse waveform based upon the at least one determined relevant gradient amplitude.

11. A non-transitory computer-readable medium having instructions stored thereon that, when executed by a controller of a magnetic resonance system, cause the magnetic resonance system to verify that diffusion-weighted measurement data of an examination object is capable of being acquired via the magnetic resonance system when using a measurement protocol with non-trapezoidal gradient pulse waveforms for diffusion encoding by:
loading a non-trapezoidal gradient pulse waveform;
loading predetermined characteristics for the loaded non-trapezoidal gradient pulse waveform;
receiving a condition that is satisfied when the diffusion-weighted measurement data is acquired;
determining at least one relevant gradient amplitude for the loaded non-trapezoidal gradient pulse waveform based upon the loaded predetermined characteristics and the condition; and
verifying that the diffusion-weighted measurement data is capable of being acquired when using the measurement protocol with the loaded non-trapezoidal gradient pulse waveform based upon the at least one determined relevant gradient amplitude.
